(19) United States
(12) Patent Application Publication
(10) Pub. No.: US 2025/0215316 A1
(43) Pub. Date: Jul. 3, 2025

(54) QUANTUM DOT, PREPARATION METHOD FOR QUANTUM DOT, AND PHOTOELECTRIC DEVICE

(71) Applicant: TCL TECHNOLOGY GROUP CORPORATION, Huizhou, Guangdong (CN)

(72) Inventor: Jianchao GE, Huizhou, Guangdong (CN)

(73) Assignee: TCL TECHNOLOGY GROUP CORPORATION, Huizhou, Guangdong (CN)

(21) Appl. No.: 18/852,494

(22) PCT Filed: Nov. 2, 2022
(86) PCT No.: PCT/CN2022/129162

§ 371 Date: Sep. 29, 2024

(30) Foreign Application Priority Data
Apr. 1, 2022 (CN) 202210347952.5

(51) Int. Cl. C09K 11/88; B82Y 30/00; C09K 11/02; H10H 20/822

(52) U.S. Cl. CPC C09K 11/883; B82Y 30/00; C09K 11/02; H10H 20/822

(57) ABSTRACT

The present application discloses a quantum dot, a preparation method for the quantum dot, and a photoelectric device. The quantum dot comprises a core structure and a shell structure; the shell structure wraps the core structure; the material of the core structure is selected from one or two of CdSe and ZnCdSe; the shell structure is doped with molybdenum ions. The molybdenum ions can compensate for a vacancy defect of a core-shell structure to release surface stress caused based on the vacancy defect, and coordinate exposed anions of the core-shell structure to improve the light-emitting efficiency and stability of the quantum dot.

The present application claims priority to Chinese Patent Application No. 202210347952.5, filed on Apr. 1, 2022, and entitled “QUANTUM DOT AND PREPARATION METHOD THEREFOR, AND PHOTOELECTRIC DEVICE”, the entire contents of all of which are incorporated herein by reference.

### TECHNICAL FIELD

The present disclosure relates to a technical field of photoelectric technology, and in particular to a quantum dot and preparation method therefor, and a photoelectric device.

### BACKGROUND

A quantum dot refers to a semiconductor crystal that has a quantum confinement effect in three dimensions of space. The dependence of optical properties on particle size is a unique and attractive feature of the quantum dot. For example, by controlling the size of particles, an emitted light wave of a CdSe quantum dot is continuously tunable throughout the whole visible light range. The quantum dot has characteristics of high brightness, narrow half-peak width, and adjustable wavelength, thus the quantum dot has a broad application prospect in photoelectric equipments, fluorescent labeling and other fields.

### Technical Solutions

Accordingly, the present disclosure provides a quantum dot and preparation method therefor, and a photoelectric device to improve a problem of lattice mismatch or incomplete coating of a core layer by a shell layer in a traditional core-shell quantum dot structure.

In a first aspect, the present disclosure provides a quantum dot including:
a core structure, wherein a material of the core structure is selected from one or more of CdSe and ZnCdSe; and
a shell structure, wrapping the core structure, and doped with molybdenum ions.

Alternatively, a material of the shell structure is selected from one or more of ZnS, ZnCdS, ZnS/ZnS, ZnS/ZnCdS, ZnSe/ZnS/ZnS, ZnSe/ZnS/ZnCdS, ZnCdSe/ZnS, ZnCdSe/ZnCdS, ZnSe/ZnSe/ZnS, ZnSe/ZnSe/ZnCdS, ZnCdSe/ZnCdSe/ZnS, and ZnCdSe/ZnCdSe/ZnCdS.

Alternatively, the shell structure is a single shell layer or multiple shell layers, and one shell layer or multiple shell layers of the shell structure are doped with the molybdenum ions.

Alternatively, any shell layer of the shell structure is obtained by a reaction of a cationic precursor and an anionic precursor; the cationic precursor includes one or more of a zinc precursor and a cadmium precursor, and the anionic precursor includes one or more of a selenium precursor and a sulfur precursor.

Alternatively, the zinc precursor is selected from one or more of zinc acetate, zinc chloride, zinc oleate, zinc decanate, zinc undecylenate, zinc stearate and zinc diethyldithiocarbamate; the cadmium precursor is selected from one or more of cadmium acetate, cadmium chloride, cadmium oleate, cadmium dedecanoate, cadmium undecylenate, cadmium stearate and cadmium diethyldithiocarbamate; the selenium precursor is selected from one or more of TOP-Se, ODE-Se, DPP-Se and a suspension of Se; the sulfur precursor is selected from one or more of TOP-S, ODE-S, DPP-S and a suspension of S.

Alternatively, in the shell layer doped with the molybdenum ions, a molar mass ratio of doped molybdenum ions to the anionic precursor forming the shell layer is less than 1:100.

Alternatively, a structural composition of the quantum dot is selected from one of the following:
(a) the quantum dot is CdSe/ZnMoS, the core structure of the quantum dot is CdSe, and the shell structure of the quantum dot is ZnMoS;
(b) the quantum dot is CdSe/ZnCdMoS, the core structure of the quantum dot is CdSe, and the shell structure of the quantum dot is ZnCdMoS;
(c) the quantum dot is CdSe/ZnMoS/ZnS, the core structure of the quantum dot is CdSe, and the shell structure of the quantum dot is ZnMoS/ZnS;
(d) the quantum dot is CdSe/ZnMoS/ZnCdS, the core structure of the quantum dot is CdSe, and the shell structure of the quantum dot is ZnMoS/ZnCdS;
(e) the quantum dot is CdSe/ZnSe/ZnMoS/ZnS, the core structure of the quantum dot is CdSe, and the shell structure of the quantum dot is ZnSe/ZnMoS/ZnS;
(f) the quantum dot is CdSe/ZnSe/ZnMoS/ZnCdS, the core structure of the quantum dot is CdSe, and the shell structure of the quantum dot is ZnSe/ZnMoS/ZnCdS;
(g) the quantum dot is ZnCdSe/ZnMoSe/ZnSe/ZnS, the core structure of the quantum dot is ZnCdSe, and the shell structure of the quantum dot is ZnMoSe/ZnSe/ZnS;
(h) the quantum dot is ZnCdSe/ZnMoSe/ZnSe/ZnCdS, the core structure of the quantum dot is ZnCdSe, and the shell structure of the quantum dot is ZnMoSe/ZnSe/ZnCdS;
(i) the quantum dot is ZnCdSe/ZnCdSe/ZnCdMoS/ZnS, the core structure of the quantum dot is ZnCdSe, and the shell structure of the quantum dot is ZnCdSe/ZnCdMoS/ZnS.

Alternatively, an average particle size of the core structure of the quantum dot is 3 nm-10 nm, and a thickness of the shell structure of the quantum dot is less than 10 nm.

In a second aspect, the present disclosure provides a preparation method for a quantum dot including:
providing a core structure solution including a core structure selected from one or more of CdSe and ZnCdSe;
providing a shell structure precursor solution, wherein the shell structure precursor solution includes a shell structure precursor and a molybdenum precursor; and
mixing and reacting the shell structure precursor solution with the core structure solution, in order to form a shell structure doped with molybdenum ions on a surface of the core structure to obtain the quantum dot.

Alternatively, the material of the shell structure is selected from one or more of ZnS, ZnCdS, ZnS/ZnS, ZnS/ZnCdS, ZnSe/ZnS/ZnS, ZnSe/ZnS/ZnCdS, ZnCdSe/ZnS, ZnCdSe/ZnCdS, ZnSe/ZnSe/ZnS, ZnSe/ZnSe/ZnCdS, ZnCdSe/ZnCdSe/ZnS and ZnCdSe/ZnCdSe/ZnCdS.

Alternatively, the shell structure precursor includes a first cationic precursor and a first anionic precursor, the first cationic precursor includes one or more of a zinc precursor and a cadmium precursor, and the first anionic precursor includes one or more of a selenium precursor and a sulfur precursor;
a molar mass ratio of the molybdenum precursor to the first anionic precursor is less than 1:100.

Alternatively, the shell structure precursor solution includes a first shell structure precursor solution to an N-th shell structure precursor solution, wherein N is an integer greater than 1, and one or more of the first shell structure precursor solution to the N-th shell structure precursor solution include the molybdenum ions.

Alternatively, a step of mixing and reacting the shell structure precursor solution with the core structure solution includes mixing the first shell structure precursor solution to the N-th shell structure precursor solution with the core structure solution sequentially.

Alternatively, the first shell structure precursor solution to the N-th shell structure precursor solution independently include a second cationic precursor and a second anionic precursor, and the second cationic precursor includes the zinc precursor and the cadmium precursor, and the second anionic precursor includes one or more of the selenium precursor and the sulfur precursor.

Alternatively, in the first shell structure precursor solution to the N-th shell structure precursor solution, a molar mass ratio of the molybdenum precursor to the second anionic precursor is less than 1:100 for each shell structure precursor solution including the molybdenum precursor.

Alternatively, the zinc precursor is selected from one or more of zinc acetate, zinc chloride, zinc oleate, zinc decanate, zinc undecylenate, zinc stearate and zinc diethyldithiocarbamate; the cadmium precursor is selected from one or more of cadmium acetate, cadmium chloride, cadmium oleate, cadmium dedecanoate, cadmium undecylenate, cadmium stearate and cadmium diethyldithiocarbamate; the selenium precursor is selected from one or more of TOP-Se, ODE-Se, DPP-Se and a suspension of Se; the sulfur precursor is selected from one or more of TOP-S, ODE-S, DPP-S and a suspension of S; the molybdenum precursor is selected from one or more of molybdenum oleate, molybdenum laurate, and molybdenum myristate.

Alternatively, the core structure solution is obtained through steps as followed:
providing a first precursor solution including a third cationic precursor, a ligand, and a solvent;
Heating the first precursor solution to a preset temperature, wherein the preset temperature is 280° C.-300° C.;
providing a second precursor solution including the selenium precursor; and
mixing the second precursor solution with the first precursor solution to perform a first reaction stage.

Alternatively, the third cationic precursor includes the cadmium precursor, and the core structure solution is obtained through the first reaction stage; in the first reaction stage, a molar mass ratio of the cadmium precursor to the selenium precursor is 1:0.1-1:10.

Alternatively, the third cationic precursor includes the zinc precursor, and after the first reaction stage, the preparation method further includes: adding the cadmium precursor and performing a second reaction stage to obtain the core structure solution.

In a third aspect, the present disclosure provides a photoelectric device comprising:
an anode, a quantum dot light-emitting layer and a cathode sequentially disposed in stack;
wherein the quantum dot light-emitting layer is made of a quantum dot that includes:
a core structure, wherein a material of the core structure is selected from one or more of CdSe and ZnCdSe; and
a shell structure, wrapping the core structure, and doped with molybdenum ions.

### BRIEF DESCRIPTION OF THE DRAWINGS

In order to illustrate the technical solutions in the embodiments of the present disclosure more clearly, accompanying drawings involved in the description of the embodiments will be briefly described below. It will be apparent that the accompanying drawings in the following description are merely some of the embodiments of the present disclosure, and other drawings may be obtained according to these drawings for those skilled in the art without involving any inventive effort.

FIG. 1a is a schematic diagram of a lattice structure of a quantum dot according to an embodiment of the present disclosure.

FIG. 1b is a schematic diagram of a lattice structure of another quantum dot according to an embodiment of the present disclosure.

FIG. 2a is a schematic diagram of a lattice structure of a quantum dot undoped with molybdenum ions according to an embodiment of the present disclosure.

FIG. 2b is a schematic diagram of a lattice structure of a quantum dot doped with molybdenum ions according to an embodiment of the present disclosure.

FIG. 3 is a flowchart showing steps of a preparation method for a quantum dot according to an embodiment of the present disclosure.

FIG. 4 is a flowchart showing steps of S11 shown in FIG. 3.

### DETAILED DESCRIPTION OF EMBODIMENTS

Embodiments of the present disclosure will be described clearly and fully below in connection with the accompanying drawings in the embodiments of the present disclosure. It will be apparent that the described embodiments are merely a part of the embodiments of the present disclosure, rather than all the embodiments. Based on the embodiments in the present disclosure, all other embodiments obtained by a person skilled in the art without involving any inventive effort are within the scope of the present disclosure.

An embodiment of the present disclosure provides a quantum dot and preparation method therefor, and a photoelectric device. Detailed descriptions are given below. It is to be noted that the order in which the following embodiments are described is not intended to define a preferred order of the embodiments.

Additionally, in the description herein, the term “comprise” or “include” means “including, but not limited to”. Ranges may present in various embodiments of the present disclosure, and it is to be understood that the description of the ranges is merely for convenience and brevity and should not be construed as a limitation on the scope of the present disclosure. Accordingly, it is to be considered that the description of the ranges has particularly disclosed all possible subranges, as well as any single numerical value within that ranges. For example, it is to be considered that a range from 1 to 6 has particularly disclosed subranges, e.g., from 1 to 3, from 1 to 4, from 1 to 5, from 2 to 4, from 2 to 6, from 3 to 6, or the like, and single numerical values within the range, e.g., 1, 2, 3, 4, 5, or 6, which is applicable for any range. Additionally, whenever a range of values is indicated herein, it is meant to include any recited number (including a fractional or integer) within the indicated range.

In the present disclosure, the term “and/or”, indicating an association relationship of associated objects, means that there may be three relationships. For example, “A and/or B” may represent a case where A is present alone, a case where A and B are present at the same time, and a case where B is present alone, in which A and B may be a singular or plural.

In the present disclosure, the phrase “at least one” refers to one or a plurality of elements, and “more” in the “one or more” refers to two or more. The phrase “one or more” or a similar expression, refers to any combination of these elements defined by the phrase, including a singular element or any combination of the plurality of elements. For example, “at least one of a, b, or c”, or “at least one of a, b, and c”, may represent: a, b, c, a-b (i.e., a and b), a-c, b-c, or a-b-c, in which a, b, and c may be a single or plural.

As used in the present disclosure, a quantum dot refers to a semiconductor crystal that has a quantum confinement effect in three dimensions of space. When a semiconductor crystal is excited by light, an electron from the semiconductor crystal's valence band will jump to conduction band, leaving a hole in the valence band. An electron or a hole each relax to the bottom of the conduction band (top of the valence band) at an ultrafast speed, while an electron-hole pair form a whole under coulomb interaction, and the whole is usually called an exciton. The position of the hole in the exciton is relatively fixed, while the electron in a delocalized conduction band has a certain range of activities around the hole in a semiconductor. When a size of any one dimension of the semiconductor is smaller than the semiconductor's corresponding exciton bohr radius, a movement of the exciton will be restricted. Specifically, as the size of the semiconductor decreases, an energy level of the exciton will change due to a change in size, which is called a quantum confinement effect.

Defects of the quantum dot may seriously affect luminescence properties of the quantum dot. Under normal circumstances, the electron-hole pair (exciton) generated in the quantum dot should first relax within a band, then recombine at the edge of the band and emit photons. If there are defects in the quantum dot, such as lattice stacking defects (whether the defects are inside the lattice or on the surface of the lattice) and dangling coordinate bonds may cause defect energy levels to the semiconductor crystal, so that the exciton may relax to the defect energy levels. During a process of the exciton relaxing to the defect energy levels, the decay dynamic of the exciton may change due to an addition of other relaxation and recombination. Furthermore, since defect states often have a high probability of non-radiative transitions, the luminescence ability of defective quantum dot may be weakened. Photoluminescence quantum yield is a measure of the ability of the quantum dot. The photoluminescence quantum yield refers to the ratio of the number of photons emitted to the number of photons absorbed under a certain amount of light and within a certain period of time. Generally speaking, for a perfect quantum dot, when the quantum dot absorbs a photon, it can generate an exciton and emit a photon, and the photoluminescence quantum yield should be 100%. However, when the defects exist, the exciton generated by illumination may not recombine and emit photons, thus the photoluminescence quantum yield may be less than 100%.

As mentioned above, in a core-shell quantum dot structure, such as CdSe/ZnS (a lattice structure of CdSe and ZnS is shown in FIG. 1a), it may be a lattice mismatch between CdSe and ZnS due to a lattice difference. The stress caused by the lattice mismatch and incomplete shell coating cannot be released, which may produce atomic defects in the structure (as shown in FIG. 1b), which greatly affects the luminous efficiency and stability of the quantum dot. Moreover, in the core-shell structure, excess Se ions of the surface may introduce hole defects, and the hole defects are very deep. Because a deep hole emission is generated from a Se-rich crystal plane, and the Se-rich crystal plane poorly bind to most basic ligands, holes in the quantum dot are easily trapped, which has a negative impact on the recombination efficiency and light extraction efficiency of the quantum dot.

Based on this, an embodiment of the present disclosure provides the quantum dot as described below to improve a problem of lattice mismatch or incomplete shell coating of a core-shell quantum dot structure.

An embodiment of the present disclosure provides a quantum dot which includes a core structure and a shell structure, wherein the shell structure wraps the core structure, a material of the core structure is selected from one or more of CdSe and ZnCdSe, and the shell structure is doped with molybdenum ions.

By doping the shell structure with the molybdenum ions, doped molybdenum ions are added to a system of the core-shell structure. On the one hand, the doped molybdenum ions may replace cations, compensating for vacancy defects caused by the lattice difference in the core-shell structure and stress due to stacking of shell layers, and effectively improving lattice distortion caused by the lattice difference because of releasing surface stress. On the other hand, since the doped molybdenum ions with a high positive valence may coordinate with surface exposed anions to achieve passivation of the exposed anions, the defect states caused by the incomplete shell coating of the exposed anions is fixed, and a cation surface that may stably bind to alkaline ligands is generated. Accordingly, deep hole traps of anions is effectively suppressed to shield surface holes, thereby improving the luminescence efficiency and stability of the quantum dot, and enhancing device performance.

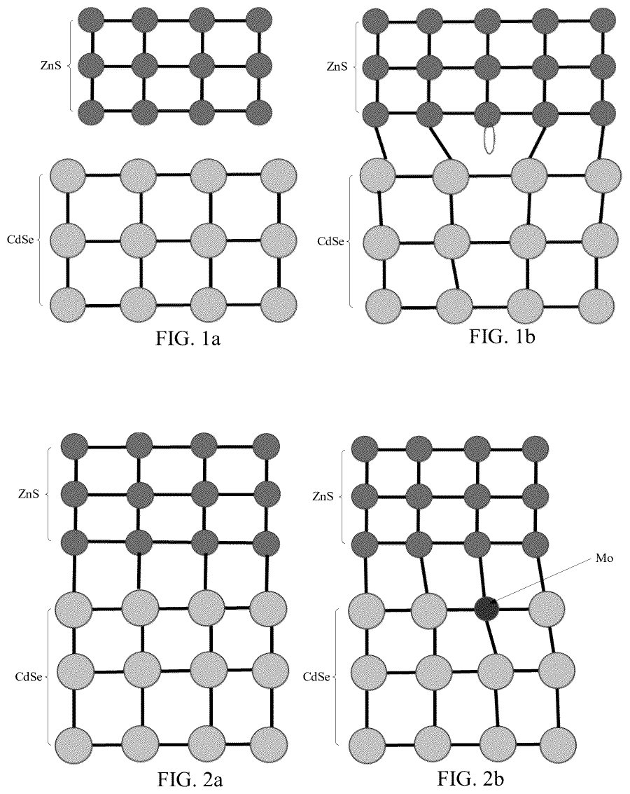

Referring to FIG. 2a, assuming that a core layer is CdSe and a shell layer is ZnS, because the lattice structure of CdSe is quite different from that of ZnS, a large stretch occurs in the structure resulting in greater stress, while the stress cannot be released, the vacancy defects may be generated. Referring to FIG. 2b, By introducing the doped molybdenum ions into CdSe/ZnS, the molybdenum ions with small particle size may replace the positions of cations in the lattice structure of the CdSe/ZnS, slowing down the stretching or twisting caused by the lattice difference in the structure, thus reducing the stress, and then reducing the generation of the vacancy defects.

In some embodiments, a material of the shell structure is selected from one or more of ZnS, ZnCdS, ZnS/ZnS, ZnS/ZnCdS, ZnSe/ZnS/ZnS, ZnSe/ZnS/ZnCdS, ZnCdSe/ZnS, ZnCdSe/ZnCdS, ZnSe/ZnSe/ZnS, ZnSe/ZnSe/ZnCdS, ZnCdSe/ZnCdSe/ZnS, and ZnCdSe/ZnCdSe/ZnCdS.

In some embodiments, a structural composition of the quantum dot is selected from one of the following:
(a) the quantum dot is CdSe/ZnMoS, wherein the core structure of the quantum dot is CdSe, and the shell structure of the quantum dot is ZnMoS;
(b) the quantum dot is CdSe/ZnCdMoS, wherein the core structure of the quantum dot is CdSe, and the shell structure of the quantum dot is ZnCdMOS;
(c) the quantum dot is CdSe/ZnMoS/ZnS, wherein the core structure of the quantum dot is CdSe, and the shell structure of the quantum dot is ZnMoS/ZnS;
(d) the quantum dot is CdSe/ZnMoS/ZnCdS, wherein the core structure of the quantum dot is CdSe, and the shell structure of the quantum dot is ZnMoS/ZnCdS;
(e) the quantum dot is CdSe/ZnSe/ZnMoS/ZnS, wherein the core structure of the quantum dot is CdSe, and the shell structure of the quantum dot is ZnSe/ZnMoS/ZnS;
(f) the quantum dot is CdSe/ZnSe/ZnMoS/ZnCdS, wherein the core structure of the quantum dot is CdSe, and the shell structure of the quantum dot is ZnSe/ZnMoS/ZnCdS;
(g) the quantum dot is ZnCdSe/ZnMoSe/ZnSe/ZnS, wherein the core structure of the quantum dot is ZnCdSe, and the shell structure of the quantum dot is ZnMoSe/ZnSe/ZnS;
(h) the quantum dot is ZnCdSe/ZnMoSe/ZnSe/ZnCdS, wherein the core structure of the quantum dot is ZnCdSe, and the shell structure of the quantum dot is ZnMoSe/ZnSe/ZnCdS;
(i) the quantum dot is ZnCdSe/ZnCdSe/ZnCdMoS/ZnS, wherein the core structure of the quantum dot is ZnCdSe, and the shell structure of the quantum dot is ZnCdSe/ZnCdMoS/ZnS.

In some embodiments, an average particle size of the core structure of the quantum dot is 3 nm-10 nm, and a thickness of the shell structure of the quantum dot is less than 10 nm.

In some embodiments, the shell structure of the quantum dot is a single shell layer or multiple shell layers, and one shell layer or multiple shell layers of the shell structure are doped with the molybdenum ions. For example, the shell structure of the quantum dot is three shell layers, and the first shell layer and the third shell layer of the three shell layers are doped with the molybdenum ions. For another example, the shell structure of the quantum dot is five shell layers, and the second shell layer and the fourth shell layer of the five shell layers are doped with the molybdenum ions.

In some embodiments, any shell layer of the shell structure is obtained by a reaction of a cationic precursor and an anionic precursor, wherein the cationic precursor includes one or more of a zinc precursor and a cadmium precursor, and the anionic precursor includes one or more of a selenium precursor and a sulfur precursor.

In some embodiments, in the shell layer doped with the molybdenum ions, a molar mass ratio of the doped molybdenum ions to the anionic precursor forming the shell layer is less than 1:100. For example, the shell structure of the quantum dot is three shell layers in which the first shell layer and the third shell layer are doped with the molybdenum ions, the molar mass ratio of the first shell layer to the anionic precursor forming the first shell layer is less than 1:100, and the molar mass ratio of the third shell layer to the anionic precursor forming the third shell layer is less than 1:100.

It can be understood that in the shell layer doped with the molybdenum ions, if the anionic precursor forming the shell layer is the selenium precursor, the molar mass ratio of the molybdenum ions doped into the shell layer to the selenium precursor is less than 1:100; if the anionic precursor forming the shell layer is the sulfur precursor, the molar mass ratio of molybdenum ions doped into the shell layer to the sulfur precursor is less than 1:100. Upon a condition that the anionic precursor forming the shell layer is the selenium precursor and the sulfur precursor, the molar mass ratio of molybdenum ions doped into the shell layer to the sum of the molar masses of the selenium precursor and the sulfur precursor is less than 1:100.

In some embodiments, the zinc precursor is selected from one or more of zinc acetate, zinc chloride, zinc oleate, zinc decanate, zinc undecylenate, zinc stearate and zinc diethyldithiocarbamate.

In some embodiments, the cadmium precursor is selected from one or more of cadmium acetate, cadmium chloride, cadmium oleate, cadmium dedecanoate, cadmium undecylenate, cadmium stearate and cadmium diethyldithiocarbamate.

In some embodiments, the selenium precursor is selected from one or more of TOP-Se, ODE-Se, DPP-Se and a suspension of Se.

In some embodiments, the sulfur precursor is selected from one or more of TOP-S, ODE-S, DPP-S and a suspension of S.

In some embodiments, the molybdenum precursor is selected from one or more of molybdenum oleate, molybdenum laurate, and molybdenum myristate.

In some embodiments, the quantum dot further includes surface ligands, and the surface ligands are selected from one or more of acid ligands, amine ligands, thiol ligands, cationic ligands, anionic halogen ligands, and cyclic organic ligands. The introduction of the surface ligands may make the whole quantum dot more stable, and enable the quantum dot to form a film stably and orderly, while it is beneficial to the balance of charge transport and improves luminous efficiency. Applying the quantum dot to a photoelectric device may improve the luminous performance of the device.

Embodiments of the present disclosure provide a preparation method for a quantum dot. Referring to FIG. 3, the preparation method for the quantum dot includes:
S31. providing a core structure solution including a core structure selected from one or more of CdSe and ZnCdSe;
S32. providing a shell structure precursor solution, wherein the shell structure precursor solution includes a shell structure precursor and a molybdenum precursor;
S33. mixing and reacting the shell structure precursor solution with the core structure solution, in order to form a shell structure doped with molybdenum ions on a surface of the core structure to obtain the quantum dot.

By doping the shell structure with the molybdenum ions, doped molybdenum ions are added to the core-shell structure. On the one hand, the doped molybdenum ions may replace the positions of cations, compensate for vacancy defects caused by the lattice difference in the core-shell structure and a problem of stress caused by stacking of shell layers, release surface stress, and effectively slow down lattice distortion caused by the lattice difference. On the other hand, the doped molybdenum ions have a high positive valence which may coordinate with surface exposed anions, achieve passivation of the exposed anions to repair the defect states caused by the incomplete shell coating of the exposed anions, generate a cation surface that may stably bind to alkaline ligands, effectively suppress deep hole traps of anions and shield surface holes, thereby improve the luminescence efficiency and stability of the quantum dot, and enhancing device performance.

In some embodiments, a material of the shell structure is selected from one or more of ZnS, ZnCdS, ZnS/ZnS, ZnS/ZnCdS, ZnSe/ZnS/ZnS, ZnSe/ZnS/ZnCdS, ZnCdSe/ZnS, ZnCdSe/ZnCdS, ZnSe/ZnSe/ZnS, ZnSe/ZnSe/ZnCdS, ZnCdSe/ZnCdSe/ZnS, and ZnCdSe/ZnCdSe/ZnCdS.

In some embodiments, in the S33, the shell structure precursor solution and the core structure solution are mixed and reacted in an organic solvent to form the shell structure doped with the molybdenum ions on the surface of the core structure to obtain the quantum dot.

In some embodiments, the organic solvent is a mixed solution of oleic acid (OA) and octadecene (ODE). The mixed solution of oleic acid and octadecene has good solubility for the core structure, the selenium precursor and the sulfur precursor, and the mixed solution has little polarity difference with a solvent commonly configured to dissolve the selenium precursor or dissolve the sulfur precursor, and the mixed solution has good compatibility, which is beneficial to the reaction of forming the shell on the surface of the core structure.

In some embodiments, the shell structure precursor includes a first cationic precursor and a first anionic precursor, the first cationic precursor includes one or more of the zinc precursor and the cadmium precursor, and the first anionic precursor includes one or more of the selenium precursor and the sulfur precursor.

In some embodiments, the shell structure of the quantum dot is a single shell layer or multiple shell layers, and one shell layer or multiple shell layers of the shell structure are doped with the molybdenum ions.

In some embodiments, the shell structure precursor solution includes the shell structure precursor and the molybdenum precursor, wherein the shell structure precursor includes the first cationic precursor and the first anionic precursor, and the first cationic precursor includes one or more of the zinc precursor and the cadmium precursor, and the first anionic precursor includes one or more of the selenium precursor and the sulfur precursor.

For example, the first cationic precursor is the zinc precursor, and the first anionic precursor is the sulfur precursor, and the core structure solution includes a CdSe core structure. Mixing and reacting the zinc precursor, the sulfur precursor, the molybdenum precursor and the core structure of CdSe, so as to form a ZnMoS shell structure of a single shell layer doped with the molybdenum ions on the surface of the CdSe core structure to obtain the quantum dot of CdSe/ZnMoS.

In some embodiments, a molar mass ratio of the molybdenum precursor to the first anionic precursor is less than 1:100. For example, the first anionic precursor is the selenium precursor, and the molar mass ratio of the molybdenum precursor to the selenium precursor is less than 1:100. For another example, the first anionic precursor is the sulfur precursor, and the molar mass ratio of the molybdenum precursor to the sulfur precursor is less than 1:100. For another example, the first anionic precursor is the selenium precursor and the sulfur precursor, and the molar mass ratio of the molybdenum precursor to the sum of the molar masses of the selenium precursor and the sulfur precursor is less than 1:100.

In some embodiments, the shell structure precursor solution comprises a first shell structure precursor solution to an N-th shell structure precursor solution, wherein N is an integer greater than 1, and one or more of the first shell structure precursor solution to the N-th shell structure precursor solution include the molybdenum ions. S33 includes mixing the first shell structure precursor solution to the N-th shell structure precursor solution with the core structure solution sequentially.

For example, the shell structure precursor solution includes the first shell structure precursor solution, a second shell structure precursor solution and a third shell structure precursor solution. First, add the first shell structure precursor solution to the core structure solution to form a first shell layer on the surface of the core structure, and then continue to add the second shell structure precursor solution to form a second shell layer on the first shell layer, and then continue to add the third shell structure precursor solution to form a third shell layer on the first shell layer and the second shell layer, so as to obtain the quantum dot having a core structure surrounded by a three-layers shell.

It can be understood that the shell structure precursor solution forming the corresponding shell layer includes the molybdenum precursor. As mentioned above, assuming that the second shell layer is doped with the molybdenum ions, the second shell structure precursor solution includes the molybdenum ions to form the second shell layer doped with the molybdenum ions.

In some embodiments, the first shell structure precursor solution to the N-th shell structure precursor solution independently include a second cationic precursor and a second anionic precursor, and the second cationic precursor includes the zinc precursor and the cadmium precursor, and the second anionic precursor includes one or more of the selenium precursor and the sulfur precursor.

In some embodiments, a molar mass ratio of the molybdenum precursor to the second anionic precursor is less than 1:100. For example, the second anionic precursor is the selenium precursor, and the molar mass ratio of the molybdenum precursor to the selenium precursor is less than 1:100. For another example, the second anionic precursor is the sulfur precursor, and the molar mass ratio of the molybdenum precursor to the sulfur precursor is less than 1:100. For another example, the second anionic precursor is the selenium precursor and the sulfur precursor, and the molar mass ratio of the molybdenum precursor to the sum of the molar masses of the selenium precursor and the sulfur precursor is less than 1:100.

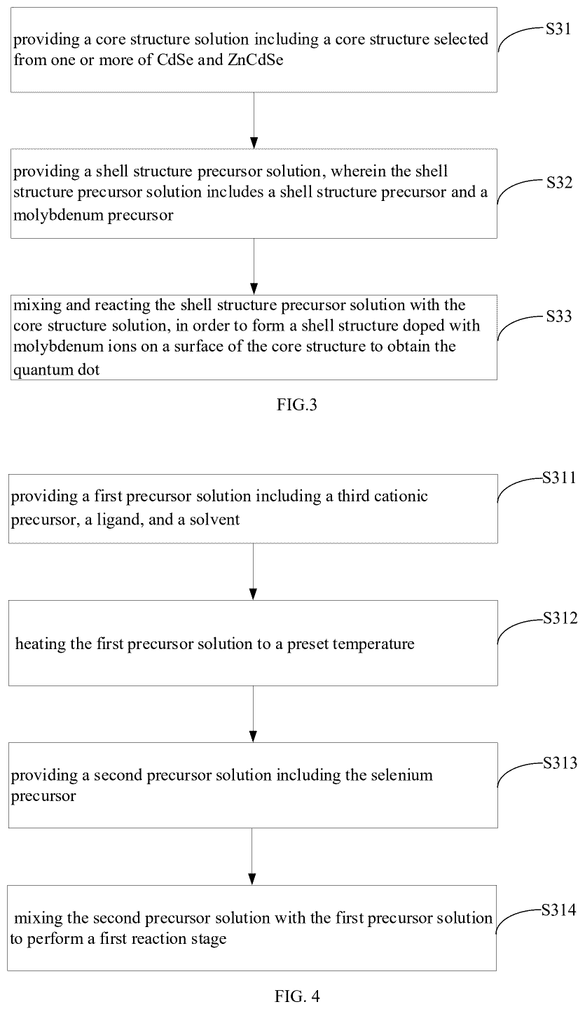

In some embodiments, referring to FIG. 4, the S31 includes:
S311. providing a first precursor solution including a third cationic precursor, a ligand, and a solvent;
S312. heating the first precursor solution to a preset temperature;
S313. providing a second precursor solution including the selenium precursor;
S314. mixing the second precursor solution with the first precursor solution to perform a first reaction stage.

In some embodiments, the preset temperature is 280° C.-300° C., such as 280° C., 290° C., 300° C., and so on.

In some embodiments, the ligand is oleic acid.

In some embodiments, the solvent is octadecene.

In some embodiments, the third cationic precursor includes the cadmium precursor, and the core structure solution is obtained through the first reaction stage.

In the first reaction stage, the cadmium precursor reacts with the selenium precursor to obtain a CdSe core structure solution.

In some embodiments, a molar mass ratio of the cadmium precursor to the selenium precursor in the first reaction stage is 1:0.1-1:10, for example 1:1.

In some embodiments, the third cationic precursor includes the zinc precursor, and after the first reaction stage, the preparation method further includes adding the cadmium precursor and performing a second reaction stage to obtain the core structure solution.

In the first reaction stage, the zinc precursor reacts with the selenium precursor, after reacting with the selenium precursor, the zinc precursor enters the second reaction stage and then reacts with the cadmium precursor to obtain a ZnCdSe core structure solution.

In some embodiments, the zinc precursor is selected from one or more of zinc acetate, zinc chloride, zinc oleate, zinc decanate, zinc undecylenate, zinc stearate and zinc diethyldithiocarbamate.

In some embodiments, the cadmium precursor is selected from one or more of cadmium acetate, cadmium chloride, cadmium oleate, cadmium dedecanoate, cadmium undecylenate, cadmium stearate and cadmium diethyldithiocarbamate.

In some embodiments, the selenium precursor is selected from one or more of TOP-Se, ODE-Se, DPP-Se and the suspension of Se.

In some embodiments, the sulfur precursor is selected from one or more of TOP-S, ODE-S, DPP-S and the suspension of S.

In some embodiments, the molybdenum precursor is selected from one or more of molybdenum oleate, molybdenum laurate, and molybdenum myristate.

In some embodiments, a preparation method for the molybdenum precursor includes the following steps:
providing a salt and a molybdenum compound;
adding the salt and the molybdenum compound to deionized water for a mixing reaction to obtain a solution including an acidic molybdenum compound;
rinsing impurities of the solution including the acidic molybdenum compound by cold ionized water to obtain a purified solution including the acidic molybdenum compound;
extracting the acidic molybdenum compound from the purified solution to obtain a solid of the acidic molybdenum compound;
Dispersing the acidic molybdenum compound in a solvent to obtain the molybdenum precursor.

In some embodiments, the salt is selected from one or more of sodium oleate, sodium laurate, and sodium myristate.

In some embodiments, the molybdenum compound is selected from one or more of molybdenum trichloride (MoCl₃), molybdenum pentachloride (MoCl₅), molybdenum trioxide (MoO₃).

In some embodiments, the acidic molybdenum compound is selected from one or more of molybdenum oleate, molybdenum laurate, and molybdenum myristate.

In some embodiments, sodium oleate and molybdenum pentachloride react in the deionized water to obtain molybdenum oleate, wherein a reaction formula is Na-oleate (sodium oleate)+MoCl₅→Mo (oleate)₅ (molybdenum oleate)+NaCl.

In some embodiments, when the salt and the molybdenum compound react in the deionized water, reaction temperature is 80 to 100 degrees Celsius and reaction time is 1 to 5 hours, for example, the reaction temperature is 85 degrees Celsius and the reaction time is 3 hours, wherein the reaction temperature refers to the temperature of the solution during the reaction.

The following is a detailed description of technical proposals and beneficial effects of the present disclosure through specific embodiments and comparative examples. The following embodiments are only part of implementation examples of the present disclosure, and are not specifically limited to the present disclosure.

### Example 1

### 1.1. Preparation of the Molybdenum Precursor.

The preparation method for the molybdenum precursor of the embodiment includes the follow processes.

0.5 mmol of sodium oleate and 4 mmol of MoCl₅ were dissolved in 2 mL of deionized water for a reaction at a temperature of 85° C. for 3 hours to obtain a solution including molybdenum oleate. Then, impurities of the solution including molybdenum oleate were rinsed repeatedly by cold deionized water to obtain a purified solution including molybdenum oleate. Molybdenum oleate was extracted from the purified solution including molybdenum oleate to obtain a solid of molybdenum oleate. The solid of molybdenum oleate was dispersed in 3 mL of ODE solution to obtain the molybdenum precursor.

### 1.2. Preparation of the Quantum Dot.

The preparation method for the quantum dot of the embodiment includes the follow processes.

Under the protection of Schlenk line (Schlenk technology), 10 mL of ZnAc₂, 10 mL of OA solution and 20 mL of ODE solution was mixed to obtain a mixed solution. The mixed solution was heated until the temperature reached 300° C., and 1 mmol of the selenium precursor was injected into the mixed solution for a reaction, and then 0.5 mmol of CdOA₂ precursor was injected into the mixed solution after an interval of 2 minutes to obtain a solution including a ZnCdSe core after 30 minutes of a reaction. The solution including the ZnCdSe core was heated until the temperature reached 300° C., and 0.2 mmol of the cadmium precursor and 1 mmol of the selenium precursor were injected for a reaction to obtain a solution including a ZnCdSe/ZnCdSe core-shell structure. The solution including the ZnCdSe/ZnCdSe core-shell structure was heated until the temperature reached 300° C., and 0.4 mmol of the cadmium precursor, 0.005 mmol of molybdenum oleate and 1 mmol of the sulfur precursor were injected for a reaction to obtain a solution including a ZnCdSe/ZnCdSe/ZnCdMoS core-shell structure. The solution including the ZnCdSe/ZnCdSe/ZnCdMoS core-shell structure was heated until the temperature reached 300° C., and 0.5 mmol of the sulfur precursor was injected for a reaction to obtain a solution including a ZnCdSe/ZnCdSe/ZnCdMoS/ZnS core-shell structure. Washing the solution including the ZnCdSe/ZnCdSe/ZnCdMoS/ZnS core-shell structure to obtain the quantum dot.

### 1.3. Preparation of the Photoelectric Device.

The preparation method for the photoelectric device of the embodiment includes the follow processes.
1.3.1. A substrate was provided as an anode, wherein the substrate had an ITO electrode structure and the thickness of the substrate was 20 nm;
1.3.2. PEDOT was spin-coated on the substrate to form a hole injection layer, wherein the speed of spin-coating was 3 kRPM and the time of spin-coating was 30 seconds, and after the spin-coating, the hole injection layer was baked in an environment of 150° C. for 30 minutes.
1.3.3. 6.5 mg/mL of TFB was spin-coated on the hole injection layer to form a hole transport layer, wherein the speed of spin-coating was 3 kRPM and the time of spin-coating was 30 seconds, and after the spin-coating, the hole transport layer was baked in an environment of 150° C. for 20 minutes.
1.3.4. 10 mg/mL of the quantum dot prepared by the preparation method for the quantum dot of the embodiment was spin-coated on the hole transport layer to form a quantum dot light-emitting layer, wherein the speed of spin-coating was 1.5 kRPM and the time of spin-coating was 30 seconds.
1.3.5. 30 mg/mL of ZnO was spin-coated on the quantum dot light-emitting layer to form an electron transport layer, wherein the speed of spin-coating was 4 kRPM and the time of spin-coating was 30 seconds, and after the spin-coating, the electron transport layer was baked in an environment of 80° C. for 10 minutes.
1.3.6. A metal Ag electrode was vapor-deposited on the electron transport layer to form a cathode, wherein the thickness of the metal Ag is 100 nm.
1.3.7. After the cathode was formed, the cathode was encapsulated to obtain the photoelectric device.

### Example 2

### 2.1. Preparation of the Molybdenum Precursor.

The preparation method for the molybdenum precursor of the embodiment includes the follow processes.

0.5 mmol of sodium oleate and 4 mmol of MoCl₅ were dissolved in 2 mL of deionized water for a reaction at a temperature of 85° C. for 3 hours to obtain a solution including molybdenum oleate. Then, impurities of the solution including molybdenum oleate were rinsed repeatedly by cold deionized water to obtain a purified solution including molybdenum oleate. Molybdenum oleate was extracted from the purified solution including molybdenum oleate to obtain a solid of molybdenum oleate. The solid of molybdenum oleate was dispersed in 5 mL of ODE solution to obtain the molybdenum precursor.

### 2.2. Preparation of the Quantum Dot.

The preparation method for the quantum dot of the embodiment includes the follow processes.

Under the protection of Schlenk line (Schlenk technology), 2 mmol of CdAc₂, 5 mL of OA solution and 20 mL of ODE solution were mixed to obtain a mixed solution. The mixed solution was heated until the temperature of which reached 300° C., and 2 mmol of the selenium precursor was injected into the mixed solution for a reaction to obtain a solution including a CdSe core. The temperature of the solution was maintained at 280° C., and 1 mmol of the sulfur precursor, 1 mmol of ZnOA, and 0.01 mmol of molybdenum oleate were injected into the solution to obtain the quantum dot of CdSe/ZnMoS with the core-shell structure.

### 2.3. Preparation of the Photoelectric Device.

Compared with the Example 1, the preparation method for the photoelectric device of the embodiment only has a difference that the quantum dot light-emitting layer was made of the quantum dot prepared by the preparation method for the quantum dot of the embodiment.

### Comparative Example 1

Compared with the Example 1, the preparation method for the photoelectric device of the Comparative Example 1 only has a difference that the molybdenum precursor was not added during the preparation of the quantum dot, and the quantum dot light-emitting layer includes quantum dots with a core-shell structure made of CdSe/ZnMOS without doping with the molybdenum ions.

### Comparative Example 2

Compared with the Example 1, the preparation method for the photoelectric device of the Comparative Example 2 only has a difference that the molybdenum precursor was not added during the preparation of the quantum dot, and the quantum dot light-emitting layer includes quantum dots with a core-shell structure made of ZnCdSe/ZnCdSe/ZnCdS/ZnS without doping with the molybdenum ions.

Performance tests were performed on the photoelectric devices of Example 1, Example 2, Comparative Example 1 and Comparative Example 2, and the results of the performance tests are shown in Table 1 below.

The test indicators include CIEmax, LT95 and LT95@1knit, wherein CIEmax refers to the maximum luminous efficiency, LT95 refers to a time taken for the maximum brightness of the device to decrease from 100% to 95% which is measured in hours, and LT95@1knit refers to the lifespan of the device.

TABLE 1

| Project Group | CIEmax | LT95 | LT95@1knit |
|---|---|---|---|
| Example 1 | 180 | 5.4 | 16993 |
| Example 2 | 188 | 4.6 | 15578 |
| Comparative | 143 | 5.2 | 11070 |
| Example 1 | | | |
| Comparative | 147 | 4.8 | 10732 |
| Example 1 | | | |

According to Table 1, the photoelectric device of the Example 1 has a higher maximum luminous efficiency, a longer time taken for the maximum brightness to decrease from 100% to 95%, and a longer lifespan of the device compared with the photoelectric device of the Comparative Example 1. It illustrates that for the quantum dot of CdSe/ZnMoS with the core-shell structure doped with the molybdenum ions in the Example 1, the molybdenum ions may replace the positions of cations, compensating for vacancy defects caused by the lattice difference in the core-shell structure and a problem of stress caused by stacking of shell layers, releasing surface stress, and effectively slowing down lattice distortion caused by the lattice difference. In addition, the molybdenum ions with high normal valence may coordinate with exposed anions to achieve passivation of the anions and repair the defect states caused by the incomplete shell coating of the exposed anions, generating the cation surface that can stably bind to alkaline ligands, effectively suppressing deep hole traps of anions and shielding surface holes, thereby improving the luminescence efficiency, the stability, and the lifespan of the device.

According to Table 1, the photoelectric device of the Example 2 has a higher maximum luminous efficiency, a longer time taken for the maximum brightness to decrease from 100% to 95%, and a longer lifespan of the device compared with the photoelectric device of the Comparative Example 2. It illustrates that for the quantum dot of ZnCdSe/ZnCdSe/ZnCdS/ZnS with the core-shell structure doped with the molybdenum ions in the Example 2 also has the above advantages, which will not be described again here.

An embodiment of the present disclosure also provides a photoelectric device including the anode, the quantum dot light-emitting layer, and the cathode sequentially disposed in stack, wherein the quantum dot light-emitting layer is made of the quantum dot as described above or the quantum dot prepared by the preparation method for the quantum dot as described above. Among them, the photoelectric device of the embodiments of the present disclosure may be applied to multiple fields or equipments such as displays, lasers, and biofluorescent markers.

Specifically, the photoelectric device described in the embodiments of the present disclosure includes a positive structure and an inverse structure.

In some embodiments, the photoelectric device with the positive structure includes the anode and the cathode disposed oppositely and the quantum dot light-emitting layer disposed between the anode and the cathode, and the anode disposed on the substrate. Furthermore, electron functional layers such as an electron injection layer, the electron transport layer, and a hole blocking layer may also be disposed between the cathode and the electron transport layer; hole functional layers such as the hole transport layer, the hole injection layer, and an electron blocking layer may also be disposed between the anode and the quantum dot light emitting layer. In some embodiments of the photoelectric device with the positive structure, the photoelectric device includes the substrate, the anode disposed on the surface of the substrate, the hole injection layer disposed on the surface of the anode, the hole transport layer disposed on the surface of the hole injection layer, the quantum dot light-emitting layer disposed on the surface of the hole transport layer, the electron transport layer disposed on the surface of the quantum dot light-emitting layer, and the cathode disposed on the surface of the electron transport layer.

In some embodiments, the photoelectric device with the inverse structure includes a stacked structure of the anode and the cathode disposed oppositely and the quantum dot light-emitting layer disposed between the anode and the cathode, and the cathode disposed on the substrate. Furthermore, electron functional layers such as an electron injection layer, the electron transport layer, and a hole blocking layer can also be disposed between the cathode and the electron transport layer; hole functional layers such as the hole transport layer, the hole injection layer, and an electron blocking layer may also be disposed between the anode and the quantum dot light-emitting layer. In some embodiments of the photoelectric device with the inverse structure, the photoelectric device includes the substrate, the cathode disposed on the surface of the substrate, the electron transport layer disposed on the surface of the cathode, the quantum dot light-emitting layer disposed on the surface of the electron transport layer, the hole transport layer disposed on the surface of the quantum dot light-emitting layer, the electron injection layer disposed on the surface of the hole transport layer, and the anode disposed on the surface of the electron injection layer.

An embodiment of the present disclosure also provides a display device including the photoelectric device as described above. The display device may be any electronic product with a display function, including but not limited to a smartphone, a tablet computer, a notebook computer, a digital camera, a digital video camera, a smart wearable device, a smart weighing electronic scale, a vehicle display, a television or an electronic book, wherein the smart wearable device may be, for example, a smart bracelet, a smart watch, a virtual reality (VR) helmet and so on. The display device of the embodiment also has the above advantages, which will not be described again here.

It can be understood that, as multiple embodiments of the present disclosure shown herein relate to one or more interlayer substances, and the positional relationship between layers uses terms such as “in stack” or “form” or “apply” or “dispose” to express. Those skilled in the art may understand that any term such as “stack” or “form” or “apply” can cover all methods, types and techniques of “in stack”. For example, sputtering, electroplating, molding, Chemical Vapor Deposition (CVD), Physical Vapor Deposition (PVD), evaporation, Hybrid Physical-Chemical Vapor Deposition (HPCVD), Plasma Enhanced Chemical Vapor Deposition (PECVD), Low Pressure Chemical Vapor Deposition (LPCVD) and so on.

The quantum dot and the preparation method therefor, and the photoelectric device provided by embodiments of the present disclosure are described in detail above, and specific examples have been applied herein to illustrate principles and implement measures. The foregoing description of embodiments is provided merely to help understand the method and the core idea of the present disclosure. For those skilled in the art, variations will be made in specific implementation and application scope in accordance with the teachings of the present disclosure. In view of the foregoing, the contents of this specification should not be construed as limiting the application.

1. A quantum dot comprising:
a core structure, wherein a material of the core structure is selected from one or more of CdSe and ZnCdSe; and
a shell structure, wrapping the core structure, and doped with molybdenum ions.

2. The quantum dot according to claim 1, wherein a material of the shell structure is selected from one or more of ZnS, ZnCdS, ZnS/ZnS, ZnS/ZnCdS, ZnSe/ZnS/ZnS, ZnSe/ZnS/ZnCdS, ZnCdSe/ZnS, ZnCdSe/ZnCdS, ZnSe/ZnSe/ZnS, ZnSe/ZnSe/ZnCdS, ZnCdSe/ZnCdSe/ZnS, and ZnCdSe/ZnCdSe/ZnCdS.

3. The quantum dot according to claim 1, wherein the shell structure is a single shell layer or multiple shell layers, and one shell layer or multiple shell layers of the shell structure are doped with the molybdenum ions.

4. The quantum dot according to claim 3, wherein any shell layer of the shell structure is obtained by a reaction of a cationic precursor and an anionic precursor; the cationic precursor comprises one or more of a zinc precursor and a cadmium precursor, and the anionic precursor comprises one or more of a selenium precursor and a sulfur precursor.

5. The quantum dot according to claim 4, wherein the zinc precursor is selected from one or more of zinc acetate, zinc chloride, zinc oleate, zinc decanate, zinc undecylenate, zinc stearate and zinc diethyldithiocarbamate; the cadmium precursor is selected from one or more of cadmium acetate, cadmium chloride, cadmium oleate, cadmium dedecanoate, cadmium undecylenate, cadmium stearate and cadmium diethyldithiocarbamate; the selenium precursor is selected from one or more of TOP-Se, ODE-Se, DPP-Se and a suspension of Se; the sulfur precursor is selected from one or more of TOP-S, ODE-S, DPP-S and a suspension of S.

6. The quantum dot according to claim 4, wherein in the shell layer doped with the molybdenum ions, a molar mass ratio of doped molybdenum ions to the anionic precursor forming the shell layer is less than 1:100.

7. The quantum dot according to claim 1, wherein a structural composition of the quantum dot is selected from one of the following:
(a) the quantum dot is CdSe/ZnMoS, the core structure of the quantum dot is CdSe, and the shell structure of the quantum dot is ZnMoS;
(b) the quantum dot is CdSe/ZnCdMoS, the core structure of the quantum dot is CdSe, and the shell structure of the quantum dot is ZnCdMoS;
(c) the quantum dot is CdSe/ZnMoS/ZnS, the core structure of the quantum dot is CdSe, and the shell structure of the quantum dot is ZnMoS/ZnS;
(d) the quantum dot is CdSe/ZnMoS/ZnCdS, the core structure of the quantum dot is CdSe, and the shell structure of the quantum dot is ZnMoS/ZnCdS;
(e) the quantum dot is CdSe/ZnSe/ZnMoS/ZnS, the core structure of the quantum dot is CdSe, and the shell structure of the quantum dot is ZnSe/ZnMoS/ZnS;
(f) the quantum dot is CdSe/ZnSe/ZnMoS/ZnCdS, the core structure of the quantum dot is CdSe, and the shell structure of the quantum dot is ZnSe/ZnMoS/ZnCdS;
(g) the quantum dot is ZnCdSe/ZnMoSe/ZnSe/ZnS, the core structure of the quantum dot is ZnCdSe, and the shell structure of the quantum dot is ZnMoSe/ZnSe/ZnS;
(h) the quantum dot is ZnCdSe/ZnMoSe/ZnSe/ZnCdS, the core structure of the quantum dot is ZnCdSe, and the shell structure of the quantum dot is ZnMoSe/ZnSe/ZnCdS;
(i) the quantum dot is ZnCdSe/ZnCdSe/ZnCdMoS/ZnS, the core structure of the quantum dot is ZnCdSe, and the shell structure of the quantum dot is ZnCdSe/ZnCdMoS/ZnS.

8. The quantum dot according to claim 1, wherein an average particle size of the core structure of the quantum dot is 3 nm-10 nm, and a thickness of the shell structure of the quantum dot is less than 10 nm.

9. A preparation method for a quantum dot comprising:
providing a core structure solution comprising a core structure selected from one or more of CdSe and ZnCdSe;
providing a shell structure precursor solution, wherein the shell structure precursor solution comprises a shell structure precursor and a molybdenum precursor; and
mixing and reacting the shell structure precursor solution with the core structure solution, in order to form a shell structure doped with molybdenum ions on a surface of the core structure to obtain the quantum dot.

10. The preparation method according to claim 9, wherein the material of the shell structure is selected from one or more of ZnS, ZnCdS, ZnS/ZnS, ZnS/ZnCdS, ZnSe/ZnS/ZnS, ZnSe/ZnS/ZnCdS, ZnCdSe/ZnS, ZnCdSe/ZnCdS, ZnSe/ZnSe/ZnS, ZnSe/ZnSe/ZnCdS, ZnCdSe/ZnCdSe/ZnS and ZnCdSe/ZnCdSe/ZnCdS.

11. The preparation method according to claim 9, wherein the shell structure precursor comprises a first cationic precursor and a first anionic precursor, the first cationic precursor comprises one or more of a zinc precursor and a cadmium precursor, and the first anionic precursor comprises one or more of a selenium precursor and a sulfur precursor;
a molar mass ratio of the molybdenum precursor to the first anionic precursor is less than 1:100.

12. The preparation method according to claim 9, wherein the shell structure precursor solution comprises a first shell structure precursor solution to an N-th shell structure precursor solution, wherein N is an integer greater than 1, and one or more of the first shell structure precursor solution to the N-th shell structure precursor solution comprise the molybdenum ions.

13. The preparation method according to claim 12, wherein a step of mixing and reacting the shell structure precursor solution with the core structure solution comprises mixing the first shell structure precursor solution to the N-th shell structure precursor solution with the core structure solution sequentially.

14. The preparation method according to claim 12, wherein the first shell structure precursor solution to the N-th shell structure precursor solution independently comprise a second cationic precursor and a second anionic precursor, and the second cationic precursor comprises the zinc precursor and the cadmium precursor, and the second anionic precursor comprises one or more of the selenium precursor and the sulfur precursor.

15. The preparation method according to claim 14, wherein in the first shell structure precursor solution to the N-th shell structure precursor solution, a molar mass ratio of the molybdenum precursor to the second anionic precursor is less than 1:100 for each shell structure precursor solution comprising the molybdenum precursor.

16. The preparation method according to claim 11, wherein the zinc precursor is selected from one or more of zinc acetate, zinc chloride, zinc oleate, zinc decanate, zinc undecylenate, zinc stearate and zinc diethyldithiocarbamate; the cadmium precursor is selected from one or more of cadmium acetate, cadmium chloride, cadmium oleate, cadmium dedecanoate, cadmium undecylenate, cadmium stearate and cadmium diethyldithiocarbamate; the selenium precursor is selected from one or more of TOP-Se, ODE-Se, DPP-Se and a suspension of Se; the sulfur precursor is selected from one or more of TOP-S, ODE-S, DPP-S and a suspension of S; the molybdenum precursor is selected from one or more of molybdenum oleate, molybdenum laurate, and molybdenum myristate.

17. The preparation method according to claim 11, wherein the core structure solution is obtained through steps as followed:
providing a first precursor solution comprising a third cationic precursor, a ligand, and a solvent;
heating the first precursor solution to a preset temperature, wherein the preset temperature is 280° C.-300° C.;
providing a second precursor solution comprising the selenium precursor; and
mixing the second precursor solution with the first precursor solution to perform a first reaction stage.

18. The preparation method according to claim 17, wherein the third cationic precursor comprises the cadmium precursor, and the core structure solution is obtained through the first reaction stage; in the first reaction stage, a molar mass ratio of the cadmium precursor to the selenium precursor is 1:0.1-1:10.

19. The preparation method according to claim 17, wherein the third cationic precursor comprises the zinc precursor, and after the first reaction stage, the preparation method further comprises: adding the cadmium precursor and performing a second reaction stage to obtain the core structure solution.

20. A photoelectric device comprising:
an anode, a quantum dot light-emitting layer and a cathode sequentially disposed in stack;
wherein the quantum dot light-emitting layer is made of a quantum dot that comprises:
a core structure, wherein a material of the core structure is selected from one or more of CdSe and ZnCdSe; and
a shell structure, wrapping the core structure, and doped with molybdenum ions.
